(19) United States
(12) Patent Application Publication
(10) Pub. No.: US 2007/0108161 A1
(43) Pub. Date: May 17, 2007

(54) Chamber components with polymer coatings and methods of manufacture

(75) Inventors: Laxman Murugesh, San Ramon, CA (US); Trung T. Doan, Los Gatos, CA (US)

Correspondence Address: JANAH & ASSOCIATES, P.C., 650 DELANCEY STREET, SUITE 106, SAN FRANCISCO, CA, 94107, US

(73) Assignee: Applied Materials, Inc.

(21) Appl. No.: 11/283,031

(22) Filed: Nov. 17, 2005

(51) Int. Cl. B44C 1/22; C23C 16/00; C03C 15/00

(52) U.S. Cl. 216/63; 118/715; 118/726

(57) ABSTRACT

A process chamber component comprises a first surface, which in use is exposed to an energized gas in the chamber, the first surface comprising a parylene coating, and second surface, which in use is not exposed to the energized gas. The interior surfaces of a process chamber can be coated, in situ, with the polymer coating. A portable fixture can be used to form the polymer coating in the process chamber. A previously coated chamber component can also be refurbished by stripping the polymer with ozone and/or oxygen and recoating with a polymer.

### BACKGROUND

Embodiments of the present invention relate to chamber components having polymer coatings.

In the processing of substrates, such as semiconductor wafers and displays, a substrate is placed in a process chamber and exposed to an energized gas to deposit or etch material on the substrate. During such processing, process residues are generated and deposited on internal surfaces of the chamber. For example, in the etching of a dielectric or metal layers, residues formed of etched materials such as etched photoresist and etchant gases, typically called etch polymer, deposit upon chamber surfaces. In subsequent process cycles, the accumulated process residues “flake off” the chamber surfaces and fall upon and contaminate the substrate. Accumulation of these residues on chamber surfaces and components interfere with their proper operation and affect the manufacturing process by altering process chemistries. Thus, the chamber is periodically cleaned to remove the accumulated process residues after a certain number of substrates have been processed.

However, cleaning processes that effectively etch off process residues often require excessive reconditioning of the chamber after cleaning. For example, in a typical wet cleaning, the chamber is opened to the atmosphere and cleaned using an acid or solvent to scrub off and dissolve process residues accumulated on the chamber walls. To provide consistent chamber surface properties, after wet cleaning, the chamber is seasoned by pumping down the chamber for an extended period of time, and thereafter, performing a series of process runs on dummy wafers. Seasoning is performed so that the internal chamber surfaces have consistent surface chemical groups; otherwise, processes performed in the chamber produce inconsistent results. In the pump-down process, the chamber is maintained in a high vacuum environment for 2 to 3 hours to outgas moisture and other volatile species trapped in the chamber during the wet clean process. Thereafter, the cleaning process is run to etch a number of dummy wafers until the chamber provides consistent and reproducible etching properties. These cumulative steps result in excessive down time for the chamber.

Plasma or dry cleaning processes result in less down time for the chamber but can also cause greater erosion of underlying chamber surfaces. In a typical process, a fluorine containing gas, such as NF₃, is passed into the chamber and a plasma is formed to clean off the process residues. While the dry cleaning step can be performed in less time, the erosive cleaning gas often erode the underlying chamber surfaces creating contaminants comprising erosion by-products. Process chambers are generally constructed of aluminum or its alloys, although materials such as quartz or silicon dioxide are also used. The inside surface of the aluminum chambers can be eroded by fluorine containing gases to AlF₃ vapors, while quartz chambers can also be eroded by fluorine gases to form SiF₄ vapors.

Thus it is desirable to protect internal chamber surfaces from erosion by process gases and cleaning plasmas. It is further desirable to reduce contamination of the substrates from flaked off process residues and erosion by-products. It is also desirable to clean chamber surfaces to remove adhered process residues without excessive erosion of underlying chamber surfaces.

### SUMMARY

A process chamber component comprises a first surface which in use is exposed to an energized gas in the chamber, the first surface comprising a parylene coating, and second surface which in use is not exposed to the energized gas and is absent the parylene coating.

A fixture for forming a polymizerable vapor for coating a polymer on a process chamber comprises an inlet for receiving a polymizerable vapor, a chamber for forming the polymerizable vapor; and an outlet for introducing the polymerizable vapor into the process chamber. Optionally, the fixture can include a vaporizer to form a polymerizable vapor.

In a method of refurbishing a process chamber components having a polymer coating, the process chamber is refurbished by removing the polymer coating and selectively coating a polymer coating on surfaces of the chamber components. For example, the polymer coating can be removed with energized oxygen or ozone gas. The polymer coating can be parylene.

### DRAWINGS

These features, aspects, and advantages of the present invention will become better understood with regard to the following description, appended claims, and accompanying drawings, which illustrate an example of the invention. However, it is to be understood that each of the features can be used in the invention in general, not merely in the context of the particular drawing, and the invention includes any combination of these features, where:

FIG. 1 is a schematic diagram of a polymer deposition apparatus;

FIG. 2 is a schematic diagram of a portable fixture used for the deposition of the polymer into a process chamber; and

FIG. 3 is a cross-sectional diagram of an exemplary process chamber.

### DESCRIPTION

A polymer film is formed on internal surfaces of process chamber components to protect the internal surfaces, during use of the chamber, from erosion by energized process, cleaning gases, and the like. The polymer film can be used to coat chamber components made from, for example, metals such as aluminum and its alloys, or ceramic materials such as for example, aluminum oxide, aluminum nitride, silicon oxide, silicon carbide and quartz. Typically the polymer coating is formed on component surfaces, which, in use, are exposed to an energized gas in the chamber. Other component surfaces which are not exposed to the energized gas or which are in contact with other chamber component surfaces are not coated with, or absent, the polymer coating.

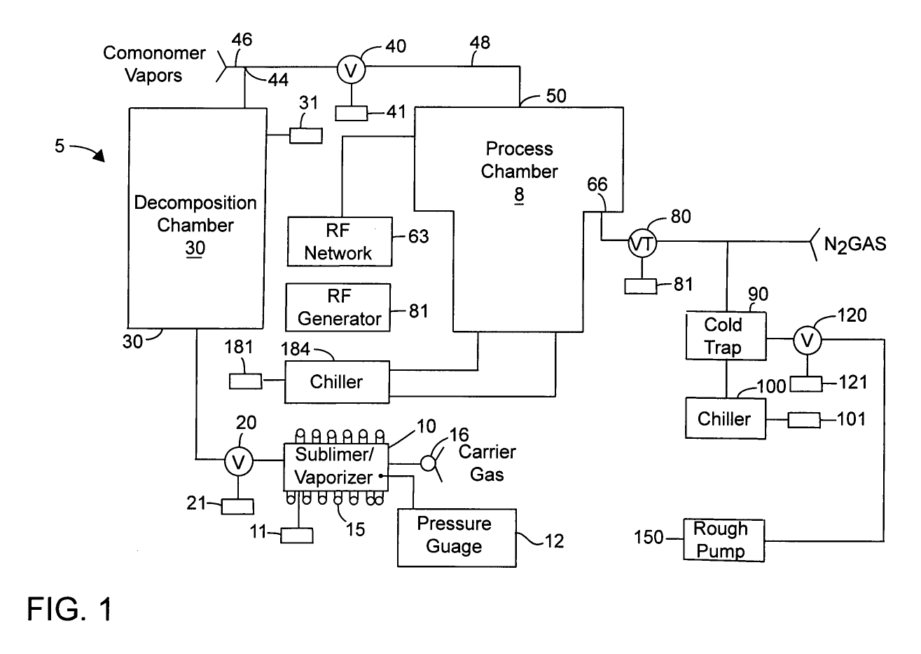

An exemplary polymer coating apparatus 5 capable of coating the internal surfaces of a process chamber 8 is illustrated in FIG. 1. Generally, the apparatus 5 comprises a vaporizer 10 that is provided to heat and vaporize a polymer precursor, which may be a solid monomer. For example, a polymer coating of coating can be formed from a solid monomer such as di-p-xylylene or substituted di-p-xylylene, as described below. Within vaporizer 10, is a containment vessel (not shown) for placement of the polymerizable starting material. The vaporizer 10 vaporizes the solid material to a vapor pressure set by controlling the amount of vaporizable material placed in the vaporizer 10 and by setting the temperature maintained in the vaporizer 10. A heated pressure gauge 12 can be used to monitor the vapor pressure of the vapor formed in the vaporizer 10. The pressure gauge 12 is heated so that the vaporized material does not deposit on the pressure gauge and render the gauge inoperable. The vaporizer 10 can also blend the vapor of one material with the vapor of another material.

A gas inlet port 342 permits the flow of a carrier gas from a carrier gas source 16 into the vaporizer 10 to drive the vapor out of the vaporizer. The carrier gas can be any inert gas, preferably helium, argon, or nitrogen. However, it should be recognized that the process might be carried out using only the vaporized reactant, e.g., parylene dimer, without the use of carrier gases.

Alternatively, when the polymer precursor is a liquid material, the vaporizer 10 can also have a bubbler (not shown) for bubbling carrier gas through a liquid polymerizable material to form a vapor of the liquid material. While a vaporizer 10 is described in an embodiment of the present invention, the polymer precursor can also be a gas that is capable of polymerizing.

The entire apparatus 5 including the process chamber 8, vaporizer 10, and decomposition chamber 30 is maintained at a pressure suitable for allowing transport of vaporized material to the chamber 8. Preferably, the pressure in the apparatus 5 is maintained at from 30 mTorr to about 5 Torr, during coating of the chamber with the vaporized polymer precursor. For vaporization of non-substituted di-p-xylylene, the pressure will preferably range from about 100 mTorr to about 1 Torr. For other monomers and polymers, the total pressure can range from 100 mTorr to about 5 Torr. The increase in total pressure up to 5 Torr increases the deposition rate of the polymer and allows better control of the amount of monomer or polymer that is provided to the deposition chamber 30. However, in some embodiments, the pressure in vaporizer 10 may be maintained at atmospheric pressure.

The vaporizer 10 may be heated by any heating means such as, for example, a heating coil 15 which may be wrapped around the vaporizer 10 to provide heat. The heating coil 15 is connected to an external electrical power source 11 which may provide an adjustable power level to the heating coil 15 to provide sufficient heat to vaporizer chamber 10 to heat the polymer precursor material to the vaporization temperature. However an excessively high temperature can cause the polymer precursor to decompose so the temperature should be controlled. An external heat controller can also be used in connection with the heating coil 15 to maintain the desired temperature. While the operating temperature of the vaporizer 10 can vary according to the material to be vaporized, the temperature is preferably maintained between from about 100 to about 200° C.

A gate valve 20 separates vaporizer 10 from decomposition chamber 30. The gate valve 20 following the vaporizer 10 may be manually operated. The gate valve 20 can also be automatically operated by a valve controller 21, which receives feedback signals of the temperature and pressure in the vaporizer 10. The valve 21 controller 21 is programmed to open the gate valve 20 only after the vaporizer 10 reaches a temperature at which the polymer precursor is vaporized so that the carrier gases flowing though the vaporizer 10 carry the vapors through the vaporizer 10 and the first valve 20. The carrier gases, which are optionally introduced into the vaporizer 10 through gas inlet port 342, are also heated by the heat radiating or being conducted from the vaporizer 10 to transfer heat to the vaporizable material.

The vaporized precursor or mixture of vaporized precursor and carrier gas, passes from vaporizer 10 through a gate valve 20 to a decomposition chamber 30 in which the vapors are partially decomposed to a monomer. For example, a vaporized di-p-xylylene dimer can be at least partially decomposed to a reactive monomer, such as p-xylylene, in the decomposition chamber 30. It should be recognized that when the polymer precursor is a monomer or oligomer that does not require vaporization or decomposition to produce a reactive species, then the vaporizer 10 and decomposition chamber 30 may be removed or bypassed. It should also be recognized that when the starting material is a dimer in a gas phase then the vaporizer 10 may also be removed or bypassed.

After the vaporized dimer is heated in the decomposition chamber 30 to produce a reactive monomer, the reactive monomer is passed into the process chamber 8. The monomer coats the exposed interior surfaces of the process chamber 8, which include exposed chamber components. The temperature of the process chamber, pressure and residence time of the gaseous reactants in the process chamber can be controlled to achieve the desired coating properties. The decomposition chamber 30 is portable and can be incorporated into a computer-controlled multi-chamber integrated processing system wherein in situ coating of a polymer and processing of a substrate is performed in the same process chamber 8. The substrate processing can include etching or deposition of material on the substrate. The chamber can also be plasma cleaned. Un-deposited gas, such as unreacted monomeric vapors, exiting the process chamber 8 can be recaptured via a cold trap 90.

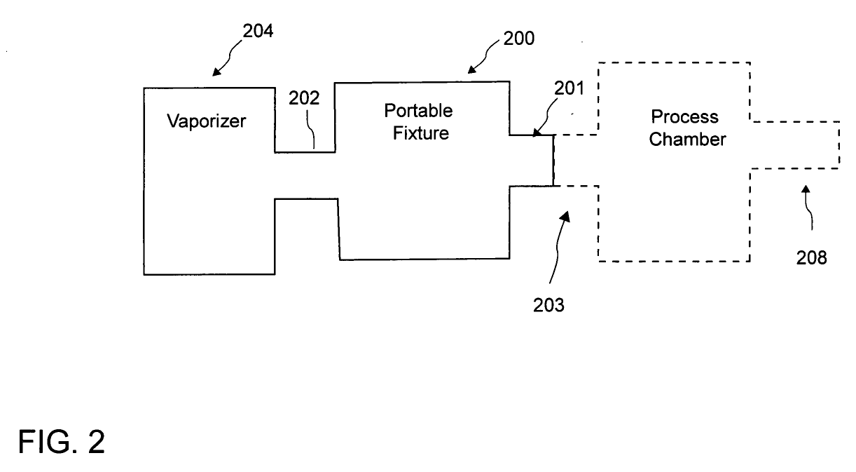

While the decomposition chamber 30 may be constructed in many ways, it is preferred that the chambers have a large surface area to heat the vaporized material rapidly and evenly. Furthermore, the decomposition chamber in this invention is engineered into a portable fixture 200 as shown in FIG. 2 and contains the same elements of decomposition chamber 30. The decomposition chamber 30 can comprise a metal cylinder (not shown). Surrounding the metal cylinder is a furnace having heating wires (not shown) to heat the vapor entering the decomposition chamber. The heater wires of the furnace are connected to an external power supply, temperature controller 31, to maintain a temperature between 400° C. and about 900° C., and preferably above about 700° C. A temperature above 400° C. and above about 700° C. is necessary to assure sufficient decomposition of the stable dimer into the reactive monomer, while the maximum temperature should not exceed about 900° C. to avoid decomposition of the monomer formed in the decomposition chamber 30. It should again be recognized that the decomposition temperature would vary according to the dimer material being used.

It is preferred that the decomposition chamber 30 decompose a sufficient amount of the dimer during its passage through the chamber to form the reactive monomer to prevent the deposition of unwanted particles on the process chamber surfaces or the formation of lumps in the deposited coating. A dimer that has not been decomposed will not polymerize, and may, therefore, cause lumps in the coating as it deposits on the surfaces, cause unwanted particles on the surface, or pass through the deposition chamber and clog the cold trap mechanism.

To ensure a high level of decomposition of the stable dimer vapors, it is preferred that the dimer vapor be sufficiently heated in the decomposition chamber 30. This can be accomplished either by increasing the surface area within the decomposition chamber 30 in contact with the vaporized dimer, or by extending the residence time of the vaporized dimer in decomposition chamber 30, or by a combination of both. Extension of the residence time in the decomposition chamber may be provided by regulating the flow rate of vaporized dimer into decomposition chamber 30, such as by regulating the flow of carrier gas into vaporizer 10; or by throttling gate valves 20 and 40; or by a combination of such valve throttling and carrier gas flow rate control. The residence time can also be controlled by the length of decomposition chamber 30, i.e., by lengthening metal cylinder (not shown) inside the decomposition chamber. To enhance decomposition of the dimer to reactive monomer, a plasma may be established in the process chamber to provide sufficient heat to decompose any stable precursor material into reactive material for subsequent deposition and polymerization on interior surfaces of the process chamber.

The gas/vapor flow containing the active monomer then passes out of decomposition chamber 30 to an optional tee 44 where the vapors are optionally blended with a comonomer in vaporized form from conduit 46. The vaporized monomer and optional comonomer then flow through a second gate valve 40 to a conduit 48 which connects valve 40 with an entrance port 50 to a process chamber 8 where the monomer deposits and polymerizes on the surfaces therein. The second gate valve 40 is controlled by valve controller 41. Conduit 48 is preferably heated, for example by heating tape, to avoid condensation therein. Where further vaporization and/or decomposition of the polymerizable material is not necessary, polymerizable material is introduced at tee 44 for direct communication to the chamber 8 and the vaporizer 10 and decomposition chamber 30 may be eliminated.

It is preferred that the walls of deposition chamber 8 be maintained at about room temperature to allow deposition and polymerization of the vaporized polymerizable material on the selected process chamber surfaces. The chamber walls may be cooled by any cooling means to maintain the interior of the process chamber at or about room temperature, such as a first chiller 184, which is controlled by temperature controller 181. The process chamber is masked to protect desired surfaces from being coated. The remaining gas/vapor mixture then passes from deposition chamber 8 through a throttle valve 80, under the control of valve controller 81, which regulates the pressure in chamber 8, and then passes through a cold trap 90 connected to a chiller 100, which is controlled by temperature controller 101. The remaining gases then pass through a gate valve 120, controlled by valve controller 121, to a rough pump 150.

A continuous supply of reactive polymerizable material can be introduced into the process chamber through a gas inlet. An inert carrier gas such as helium or argon can be used to supply the reactive polymerizable material into the process chamber. This inert gas and the RF bias may be used to form a plasma within the processing chamber in some applications.

In one embodiment, the apparatus may be provided with an RF generator 61, which is coupled to chamber 8 through an RF network 63 to permit generation of a plasma within chamber 8. The plasma may be used to enhance the decomposition of stable precursors by generating enough heat to convert the stable dimer into the reactive species. In addition, the RF generator enables integration of the chamber so that either etching of a substrate or in situ cleaning of chamber 8 can be performed.

A portable fixture 200, as shown in FIG. 2, can contain the decomposition chamber 30 and/or the vaporizer 204. In one version, the portable fixture 200, contains only the decomposition chamber 30, and either a separate vaporizer 204 is attached to the inlet 202 of the portable fixture 200 or an existing vaporized dimer, such as di-p-xylylene from another gas source other than a vaporizer is introduced into inlet 202. This portable fixture attaches to entrance port 203 of process chamber through conduit 201 to introduce the reactive monomer into the process chamber 205. The excess gas from the process chamber is vented off to a cold trap 203.

In one embodiment, the polymer coating formed on the chamber components that are exposed to the interior of the chamber comprise parylene. Parylene is a thermoplastic polymer or copolymer based on p-xylylene (CH₂C₆H₄CH₂) or derivatives of p-xylylene. The non-substituted p-xylylene polymer has the formula:
—(CH₂—C₆H₄—CH₂—)ₙ—
where n is the number of monomer units in a molecule, and preferably, the value of n averages from about 100 to about 50,000. When the value of n is about 5,000, the parylene has an average molecular weight of about 500,000. Parylene can also include chlorinated or fluorinated forms of the parylene polymers produced by halogenating the monomers or the polymers.

The typical polymer precursor for making parylene is a stable cyclic dimer, di-p-xylylene, or halogenated derivative, which is available in solid form such as a powder. The dimer is vaporized or sublimed in the vaporizer 10. The vaporized precursor is decomposed in the decomposition chamber 30 to the reactive monomer for introduction into the chamber 8 to allow polymerization in the chamber 8. The dimer is commercially available from companies such as Dow Chemical, Midland, Mich. Usually the solid dimer is available in particulate form, e.g., in powder form, for ease of handling. However, the dimer pellets may be used in conjunction with a packed bed so that the solid precursor material may be liquefied or dissolved in a carrier fluid to facilitate continuous delivery of the dimer. The internal surfaces of the chamber 8 are coated with the parylene by the vaporization or sublimation of a monomer such as the stable dimer of p-xylylene, and subsequently, the pyrolytic conversion of the stable dimer into reactive p-xylylene monomer. The method can also be used to coat a polymer by the vaporization of comonomers and derivatives of the p-xylylene monomers. The vaporized material is passed into the chamber 8 to coat the exposed internal surfaces of the chamber with the reactive monomer, which is then polymerized by heat or other energy, such as UV light or even a plasma, to form a polymer coating on the internal chamber surfaces. Alternatively, the reactive monomer can be used to coat unassembled chamber components in a conventional coating chamber.

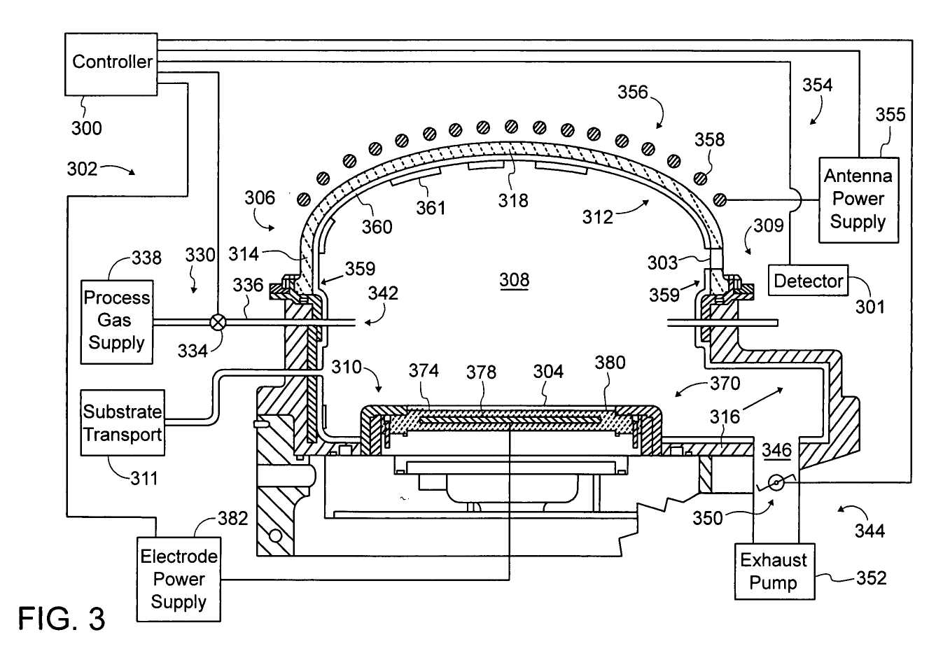

An exemplary embodiment of an apparatus 302 comprising a process chamber 306 which can be coated with the polymer coating is shown in FIG. 3. The apparatus 302 comprises a DPS type chamber, which is suitable for etching substrates 304, as is commercially available from Applied Materials, Santa Clara, Calif. The particular embodiment of the apparatus 302 is suitable for processing substrates 304, such as semiconductor substrates, and may be adapted by those of ordinary skill to process other substrates 304. The apparatus 302 is provided only to illustrate the invention, and should not be used to limit the scope of the invention or its equivalents to the exemplary embodiments provided herein.

Generally, the apparatus 302 comprises a process chamber 306 having a number of different components that can be coated using the present invention. Generally, the chamber 306 comprises walls 312 typically fabricated from metal or ceramic materials, such as the sidewalls 314, bottom wall 316, and a ceiling 318. The ceiling 318 may comprise a substantially arcuate shape, or in other versions, the ceiling 318 may comprise a dome, substantially flat, or multi-radius shaped portion. The chamber 306 is operated by a controller 300.

In operation, a gas supply 330 provides process gas into the chamber 306 from a process gas source 338. The gas supply 330 comprises a gas conduit 336 connected to the process gas source 338 and having one or more flow control valves 334 that may be used to control the flow of process gas passing through the conduit 336. The conduit 336 terminates in one or more gas inlets 342 in the chamber 306. Spent process gas and etchant byproducts are exhausted from the chamber 306 through an exhaust 344 which includes a pumping channel 346 that receives spent process gas, a throttle valve 350 to control the pressure of process gas in the chamber 306, and one or more exhaust pumps 352. The exhaust 344 may also contain an abatement system for abating undesirable gases from the exhaust.

The process gas is energized to process the substrate 304 by a gas energizer 354 that couples energy to the process gas in the process zone 308 of the chamber 306 (as shown) or in a remote zone upstream from the chamber 306 (not shown). In one version, the gas energizer 354 comprises an antenna 356 comprising one or more inductor coils 358 which may have a circular symmetry about the center of the chamber 306. Typically, the antenna 356 comprises solenoids having from about 1 to about 20 turns. A suitable arrangement of solenoids is selected to provide a strong inductive flux linkage and coupling to the process gas. When the antenna 356 is positioned near the ceiling 318 of the chamber 306, the adjacent portion of the ceiling may be made from a dielectric material, such as silicon dioxide, which is transparent to RF or electromagnetic fields. An antenna power supply 355 provides, for example, RF power to the antenna 356 at a frequency of typically about 50 KHz to about 60 MHz, and more typically about 13.56 MHz; and at a power level of from about 100 to about 5000 Watts. An RF match network (not shown) may also be provided. Alternatively or additionally, the gas energizer 354 may comprise a microwave or an “up-stream” gas activator (not shown).

In one version, the gas energizer 354 may also or alternatively comprise process electrodes 378 that may be used to energize the process gas. Typically, the process electrodes 378 include one electrode 378 in a sidewall 314 or ceiling 318 of the chamber 306 that is capacitively coupled to another electrode, such as an electrode 378 in the support 130 below the substrate 304. When the ceiling 318 also serves as an electrode 312, the ceiling 318 may comprise a dielectric material that serves as an induction field-transmitting window that provides low impedance to an RF induction field transmitted by the antenna 356 above the ceiling 318. Suitable dielectric materials that can be employed include materials such as aluminum oxide or silicon dioxide. Generally, the electrodes 312, 378 may be electrically biased relative to one another by an electrode voltage supply (not shown) that includes an AC voltage supply for providing an RF bias voltage. The RF bias voltage may comprise frequencies of about 50 kHz to about 60 MHz, and the power level of the RF bias current is typically from about 50 to about 3000 watts.

In operation, a substrate transport 311, such as for example a robotic arm (not shown) transports a substrate 304 onto the substrate support 310 in the chamber 306. The substrate 304 is typically received on lift pins (not shown) that extend out of the substrate support 310 to receive the substrate 304 and retract back into the substrate support 310 to deposit the substrate 304 on the support 310. The substrate support 310 may comprise an electrostatic chuck 370, which comprises a dielectric body 374 which at least partially covers the electrode 378 and which may include a substrate-receiving surface 380. The electrode 378 may also serve as one of the process electrodes discussed above. The electrode 378 may be capable of generating an electrostatic charge for electrostatically holding the substrate 304 to the support 310 or electrostatic chuck 370. A power supply 382 provides the electrostatic chucking voltage to the electrode 378.

The apparatus 302 further comprises one or more detectors 309 that are adapted to detect the intensities of one or more wavelengths of the radiation emission and generate one or more signals in relation to the detected intensities. A suitable detector 309 comprises a sensor 301, such as for example, a photomultiplier tube, spectrometer, charge coupled device, or photodiode. The detector 309 is typically positioned to detect the radiation emission from an energized gas in the chamber 306. For example, the detector 309 may be positioned to detect radiation passing through a window 303 formed in a wall of the chamber 306 that is permeable to radiation of the desired wavelengths. The detector 309 operates to detect the intensities of the wavelengths of radiation emission that are suitable to determine the chamber treatment or processing conditions in the chamber 306. For example, the detector 309 may be capable of detecting the intensities of radiation emissions resulting from the presence of carbon or silicon containing species in the chamber 306. Such radiation emissions are typically in the wavelength range of from about 3500 A to about 4500 A, and more typically from about 2000 A to about 8000 A. Typically, any or the entire interior chamber surfaces, and various other chamber hardware is made out of material such as aluminum or anodized aluminum or quartz.

According to an embodiment of the present invention, various chamber components, which have exposed interior chamber surfaces, can be coated with a polymer. For example, chamber components having first surfaces such as the ceiling 318, sidewalls 314 and bottom wall 316 can be selectively coated leaving second surfaces uncoated such as the lip or legs 359. To coat the chamber walls 314 and ceiling 318 so that the ceiling 318 and sidewalls 314 are easily separated from the bottom wall 316 of the present invention, the lip 359 of the process chamber are masked before coating. After the interior chamber has been coated, the mask is removed leaving the lip 359 or second surfaces of the process chamber uncoated and the first surfaces coated.

Where the desired polymer is to be selectively formed on the chamber components, the chamber components should be maintained at a temperature below the condensation temperature of the polymer precursor. For example, when coating the interior chamber surfaces with for example a polymer precursor comprising p-xylylene, the temperatures of the interior chamber surfaces should not exceed about 40° C. However, this temperature will vary depending on the polymer precursor being used to coat the interior surfaces, as would be apparent to one of ordinary skill in the art.

Referring to FIG. 1, after the mixture of vaporized gases and optional carrier gases flow into process chamber 8 a polymer may be deposited on the interior chamber surfaces. For example, parylene polymer can be deposited on interior chamber surfaces by the condensation and polymerization of the reactive p-xylylene monomers. The remainder of optional carrier gases and unreacted monomer vapors, then pass out of chamber 8 through an exit port 66 through a throttle valve 80 to a cold trap 90. The throttle valve 80 maintains the desired pressure within chamber 8. The deposition/polymerization reaction is usually carried out while maintaining a pressure within deposition chamber 8 of from about 30 milliTorr (mTorr) to 5 Torr. When the monomer is non-substituted p-xylylene, the pressure is maintained between 30 mTorr and 1 Torr, since a pressure above about 1 Torr will result in deposition of a low crystallinity film, including unreacted monomer. When the pressure in deposition chamber 8 deviates from the set pressure, throttle valve 80, which is connected to a pressure sensor, either opens to cause the pressure to drop, or closes to cause the pressure to rise.

The vapors and gases passing through throttle valve 80 then enter cold trap 90, which in turn, is connected to a vacuum pump 150, which is capable of maintaining chamber 8 at subatmospheric pressure. To prevent unreacted monomer and other copolymerizable gas from entering vacuum pump 150, but rather be removed from the gas stream in cold trap 90. Cold trap 90 may comprise any conventional commercial cold trap, which is connected to the downstream side of throttle valve 80 to trap and remove any monomers or polymers from the gas stream. Connected to the downstream side of cold trap 90 is gate valve 120 through which the remaining gases in the gas stream pass to rough vacuum pump 150 to maintain the desired low pressure.

The process chamber is selectively coated with parylene. A mask or masks are applied to desired chamber components, which are to remain uncoated. The reactive monomer coats the interior of the process chamber as described above. After coating, the masks are removed to expose the uncoated chamber component.

Chamber components, which are interchangeable or disposable or replaceable or movable or detachable, may be desired to be left uncoated. Fully coated components can be rendered immovable from the polymer coating; therefore components which may need to remain moveable may be desired to be left at least partially uncoated. For example, the top (which is integral with the sidewalls) of the DPS chamber is often separated from the bottom wall 316. To partially coat the top of the process chamber, a mask may be applied to the bottom lip the sidewalls 314 of the top before coating with the polymer. After coating, the mask over the lip is removed producing a coated chamber wherein the top and sidewalls 314 of the process chamber is detachable from the bottom wall 316 due to the uncoated lip of the process chamber top.

The polymer coated process chamber can also be refurbished after use of the chamber to process a number of substrates, or when the polymer coating on the interior chamber surfaces becomes degraded or eroded. Initially, the old or original polymer coating is stripped off in situ with an energized gas or plasma that is formed in the chamber 306. For example ozone can be introduced into the chamber 306 at a rate of 1000 sccm to reacts with a polymer coating comprising parylene to clean off the parylene coating from the chamber walls 312. In addition to ozone, an oxygen plasma can also be formed in the chamber to clean, for example, by providing oxygen at a flow rate of 100 to 1000 sccm and maintaining an RF bias of 750 to 1200 watts across the chamber electrodes. It is believed that the oxygen plasma species reacts with the parylene in a manner similar to the reaction of ozone with parylene.

Once the original polymer coating of the process chamber has been stripped with oxygen or ozone, the chamber surfaces then can be coated again with a new polymer coating. By in situ cleaning with plasma or energized gas and in situ coating of the interior surfaces of process chambers, the need to disassemble is reduced. The disassembling and assembling process chamber components can increase the mechanical wear on chamber components.

Having thus described illustrative embodiments of the invention, it will be apparent that various alterations, modifications and improvements will readily occur to those skilled in the art. Such alterations, modifications and improvements, though not expressly described above, are nonetheless intended to be implied and are within the spirit and scope of the invention. Accordingly, the foregoing discussion is intended to be illustrative only, and not limiting, the invention is limited and defined only by the following claims and equivalents thereto.

What is claimed is:

1. A process chamber component comprising:
(a) a first surface which in use is exposed to an energized gas in the chamber, the first surface comprising a parylene coating; and
(b) a second surface which in use is not exposed to the energized gas and is absent the parylene coating.

2. The component of claim 1 wherein the first surface comprises at least one of a ceiling, sidewalls, and a bottom wall of the chamber.

3. The component of claim 1 wherein the first surface comprises a dome shaped ceiling surface.

4. The component of claim 1 wherein the second surface comprises a lip around the dome shaped ceiling surface.

5. The component of claim 1 wherein the first and second surfaces are composed of aluminum or aluminum alloy.

6. The component of claim 1 wherein the first and second surfaces have an aluminum oxide coating below the parylyne coating.

7. The process chamber component of claim 1 wherein the first and second surfaces are composed of aluminum oxide, aluminum nitride, silicon oxide, silicon carbide or quartz.

8. A fixture for forming a polymizerable vapor for coating a polymer on a process chamber component in situ in the process chamber, the fixture comprising:
(a) an inlet for receiving a polymizerable vapor;
(b) a chamber for forming the polymerizable vapor; and
(c) an outlet for introducing the polymerizable vapor into the process chamber.

9. The fixture of claim 8 further comprising a vaporizer to form a polymerizable vapor.

10. The fixture of claim 9 wherein the vaporizer comprises a heater.

11. The fixture of claim 8 adapted to form a reactive monomer from a polymerizable vapor comprising di-p-xylylene.

12. A method of refurbishing a process chamber component having a polymer coating comprising:
(a) removing the polymer coating; and
(b) selectively coating a polymer coating on preselected surfaces of the chamber components.

13. The method of refurbishing of claim 12 wherein the polymer coating is removed with energized oxygen gas.

14. The method of refurbishing of claim 12 wherein the polymer coating removed with energized ozone gas.

15. The method of refurbishing of claim 12 wherein the polymer coating is parylene.

16. The method of refurbishing of claim 12 wherein (b) comprises forming the polymer coating on a first surface which in use is exposed to an energized gas in the chamber, and not forming the polymer coating on a second surface which in use is not exposed to the energized gas.

17. The method of refurbishing of claim 16 wherein the first surface comprises at least one of a ceiling, sidewalls, and a bottom wall of the chamber.

18. The method of refurbishing of claim 12 wherein the first surface comprises a dome shaped ceiling surface.

19. The method of refurbishing of claim 12 wherein the second surface comprises a lip around the dome shaped ceiling surface.

20. The method of refurbishing of claim 12 wherein the first and second surfaces are composed of aluminum, aluminum alloy, aluminum oxide, aluminum nitride, silicon oxide, silicon carbide or quartz.
